(19) United States
(12) Patent Application Publication
(10) Pub. No.: US 2005/0067272 A1
(43) Pub. Date: Mar. 31, 2005

(54) System method and collimator for oblique deposition

(75) Inventor: Kalman Pelhos, Pittsburgh, PA (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Seagate Technology LLC, Scotts Valley, CA (US)

(21) Appl. No.: 10/673,746

(22) Filed: Sep. 29, 2003

(51) Int. Cl. C23C 14/00

(52) U.S. Cl. 204/192.12; 204/298.11

(57) ABSTRACT

A deposition system and method for creating tilted thin films with azimuthal symmetry by oblique deposition. The deposition system includes a collimator for use with physical vapor deposition to provide control of the angle of incidence of the flux with improved flux throughput compared to conventional oblique deposition techniques. Additionally, the deposition system includes a collimator that may be used as a vacuum barrier for reduction of thermalization near the substrate.

### CROSS-REFERENCE TO RELATED APPLICATION(S)

The present application is related to the concurrently filed applications: Ser. No. ______, “System, Method and Aperture for Oblique Deposition;” and Ser. No. ______ “Magnetic Storage Media Having Tilted Magnetic Anisotropy.”

### BACKGROUND OF THE INVENTION

1. Field of the Invention

The present invention relates generally to the field of oblique deposition by physical vapor deposition processes. In particular, the present invention relates to an improved method for oblique deposition of tilted thin films with azimuthal symmetry on circular substrates.

2. Description of the Related Art

Physical Vapor Deposition (PVD) processes are widely used in forming many different thin films including magnetic thin films for magnetic recording media. The properties of thin films may be manipulated, not only by the choice of material deposited, but also by the method of deposition and apparatus used. In addition, the film properties are affected by the thickness and uniformity of the film, wherein the quality of the film is affected by control of those properties during deposition.

Physical vapor deposition (PVD) processes are atomistic deposition processes wherein material is vaporized from a source in the form of atoms or molecules or clusters of atoms or molecules and transported through a vacuum, low pressure or plasma environment to the substrate where it condenses. The particles vaporized from the source generally travel in a straight-line path (unless they collide with residual gas molecules/atoms) and will tend to deposit on any surface that they contact. It is important to note that the vaporized species leave the source in a flux with an angular distribution of finite (non-zero) width, i.e. there is a unique direction that most particles will travel, but there is a certain amount of dispersion from this average direction (a distribution of particles flying at slightly different angles).

Oblique deposition is a modification of the deposition process that is used to manipulate crystallographic, magnetic or other properties of thin films. Oblique deposition is the modification of deposition geometry so that the species being deposited on average strike at an angle more than 0° measured with respect to the surface normal of the substrate. Suitable systems for oblique deposition generally include physical vapor deposition (PVD) processes such as: ion beam deposition (IBD), sputtering, molecular beam epitaxy, laser ablation and vacuum evaporation. Oblique deposition generally requires directional control of the deposition process and mainly has been applied to stationary or non-rotating substrates.

However, the adaptation of PVD processes, for oblique deposition has not been successful in producing thin films with the desired properties or uniformity in the deposited material. Previous attempts to achieve tilted thin films primarily utilized one of two different techniques to attempt directional control for oblique deposition. One technique was to utilize a point-like source, for example a conventional sputter gun or IBD, to control the flux angle relative to a stationary substrate. A second technique uses a box with tilted slats placed over the immobile substrate to attempt control of the flux angle. These techniques result in poor quality thin films with an undesirably wide distribution of textures and uneven thickness. Additionally, deposition with a single point source is very slow compared to the flux volume from conventional non-oblique PVD processes, hampering use in large-scale production. The resulting thin films also have unidirectional pattern that is not desirable for applications with circular or radial pattern. Consequently, there remains a need in the art for a method of oblique deposition with sufficient throughput while maintaining incident angle control of the flux such that oblique deposited thin films with substantially uniform thickness and texture are achieved. In addition, the development of an improved method for deposition of tilted thin films with alternative configurations and azimuthal symmetry is also desired.

### BRIEF SUMMARY OF THE INVENTION

The present invention includes a deposition system and method for oblique deposition of tilted thin films. The deposition system includes a source, substrate and collimator for use in oblique deposition using physical vapor deposition processes. The deposition system controls the relationship of the vaporized species to the underlying substrate to create a well-defined symmetry in the resulting tilted thin film. The deposition system of the present invention modifies physical vapor deposition processes to create radial and/or circumferential patterns in the tilted thin films. Additionally, the deposition system can be used in physical vapor deposition processes where the substrate is rotated thereby advantageously improving the continuity and uniformity of the deposited thin film.

The collimator has a plurality of openings wherein the openings are arranged for deposition of a continuous thin film with azimuthal symmetry and/or radial or circumferential pattern. The inventive collimator is used with physical vapor deposition to provide control of flux incidence angles with improved flux throughput compared to conventional oblique deposition techniques, resulting in improved collimation. Oblique deposition using the collimator results in thin films with improved consistency of directionality, improved uniformity of thickness and smaller variance in crystallographic characteristics. Additionally, the collimator may be used as a vacuum barrier for reduction of thermalization near the substrate.

### BRIEF DESCRIPTION OF THE DRAWINGS

FIG. 1 is perspective representation of oblique deposition geometry relative to a substrate.

FIG. 2 is a perspective view with a portion cut away of the inventive deposition system.

FIG. 3 is a top view of the inventive deposition system with a sectioning wall and multiple sources.

FIG. 4 is a cross-sectional view of an embodiment of the inventive deposition system incorporating a collimator as a vacuum barrier.

FIG. 5 is a plan view of a unidirectional pattern relative to a circular substrate.

FIG. 6 is a plan view of a circumferential pattern relative to a circular substrate.

FIG. 7 is a plan view of a radial pattern relative to a circular substrate.

### DETAILED DESCRIPTION

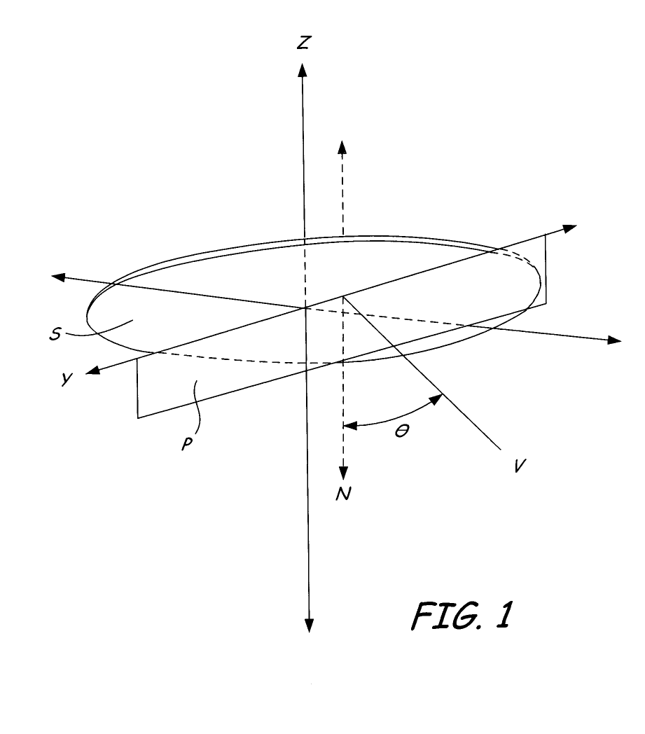

FIG. 1 shows an oblique deposition beam as a vector V striking a substrate S where the position of the vector is relative to the X, Y, and Z reference axes. Oblique deposition is generally defined as deposition geometry where a beam of atoms or particles impinges upon the surface of a wafer at a well-defined angle, θ, as measured with respect to a surface normal, N. The angle, θ, may also be referred to as the angle of incidence. Additionally, the plane of incidence P is shown. The Z axis corresponds to a central surface normal.

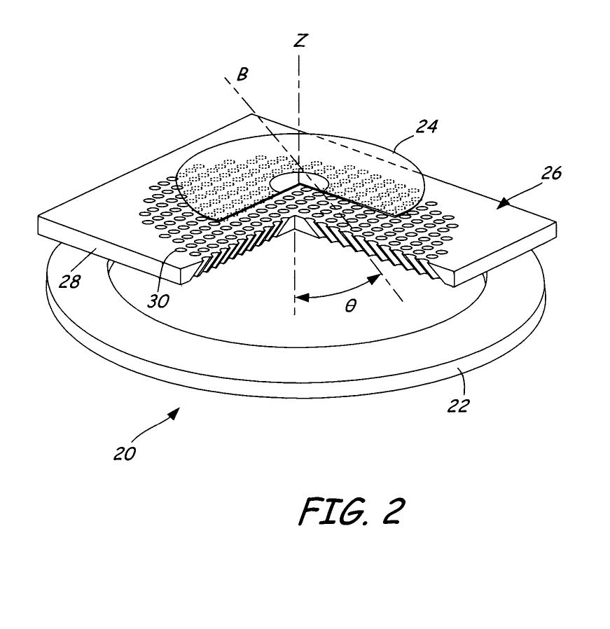

An example of deposition system 20 is shown in FIG. 2. The deposition system 20 of the present invention includes a source 22, a substrate 24 and a collimator 26 including block 28 and holes 30. The deposition system is prepared for use by placing the collimator 26 between the source 22 and the substrate 24. The deposition system 20 operates by applying energy, consistent with known methods of physical vapor deposition, to the source 22 causing the vaporization of species such as atoms, molecules or clusters. The vaporized species travel along a distribution of trajectories towards the collimator 26 and substrate 24. Vaporized species that are not aligned with the holes 30 in collimator 26 will strike block 28 and not pass through to substrate 24. Vaporized species traveling at an oblique angle so as to be aligned with the holes 30 in collimator 26 will pass through the collimator 26 and strike substrate 24 with an oblique angle of incidence. Upon contact with the surface of substrate 24, the vaporized species generally solidify, crystallize, or otherwise coagulate. As substrate 24 becomes coated with the species, a tilted thin film is formed.

The phrase “tilted thin film” of the present invention refers generally to thin films produced by oblique deposition. The “tilt” produced by oblique deposition typically refers generally to the readily observable (by electron microscopy) tilt in the grains or other crystalline related structures within a cross-section of an oblique deposited material. Use of the inventive deposition system 20 is not limited to deposition of particular types of thin films, other that the desire for the material for the thin film to be oblique deposited. The tilted thin films produced with the inventive deposition system 20; depending on the material and specifics of the physical vapor deposition process used; result in tilted grain growth, tilted crystallographic texture, anisotropic stress, correlated surface roughness, or any combination thereof. For example, the inventive deposition system may be used to deposit seedlayer structures and magnetic material layers.

The deposition system 20 reduces the variance or distribution in the tilt of the thin film by improving the collimation of the deposited species or flux, e.g. atoms, molecules and clusters. Improvement in the collimation of the deposited species generally results in improved characteristics in the tilted thin film. This improvement is apparent in methods of direct deposition of magnetic materials and methods of oblique deposition of seedlayers for magnetic materials. In magnetic data storage applications, increased distribution in orientations within thin layers of the magnetic materials is not favorable because it generally results in increased signal changes independent of the stored magnetic flux leading to reading and writing errors. Therefore it is desirable to deposit atoms/molecules/clusters in a well-collimated manner.

Deposition system 20 employs physical vapor deposition to oblique deposit material onto the surface of substrate 24. The substrate 24 is generally circular and may be formed from a variety of materials. Special preparation of the substrate 24 is typically not required. Examples of suitable materials include silicon wafers, glass discs and aluminum substrates. The source 22 is a type commonly used for physical vapor deposition processes including, but not limited to: ion beam deposition (IBD), sputtering, evaporation, molecular beam epitaxy (MBE), and pulsed laser deposition.

The deposition system 20 includes a collimator 26 placed between the source 22 and the substrate 24. The collimator 26 extends beyond the area of the substrate 24 so that the entire tilted thin film is deposited upon the surface of substrate 24 at once. The collimator 26 is a solid block 28 with a high density of holes 30. The holes 30 are drilled or otherwise prepared in the block 28. The density of holes may vary within a range from approximately 3-4 holes per square inch to billions per square inch. The collimator is desired to be highly transparent, for example greater than 90% holes. Therefore at low densities of holes, the holes are larger and at high densities of holes, the holes are smaller. The transparency of collimator 26 is preferably maximized to a limit defined by the structural integrity of block 28. The block 28 is a sheet of aluminum or other material at a thickness to be rigid during use of deposition system 20. One example of block 28 is an aluminum sheet, approximately 1 cm thick with approximately 4 holes per square inch. Another example is a block 28 with billions of micron sized holes per square inch. The holes 30 are bored at an angle, θ, measured with respect to a surface normal.

Oblique angle θ is at least approximately 35° to at most approximately 90°. Preferably oblique angle θ is between approximately 55° to approximately 75°. An example preferred angle is approximately 65°. The values of angle θ may vary from the disclosed ranges based on the desired tilt of the deposited thin film. The orientation of tilt of each hole is oriented relative to a central axis, Z, which is normal to the surface of the collimator at a central point. For example, to create a radial pattern (discussed below) in the tilted thin film, the collimator 26 will have holes 30 such that an axis B may be drawn through each hole 30, and the axis B intersects central axis Z with angle θ as shown in FIG. 2. In addition, angle θ may or may not vary amongst the holes 30 distributed in block 28. It may be desirable for the angle θ of the holes 30 to vary with the radius of the collimator, where substrate 24 is a magnetic storage disc in order to optimize track performance at different radii of the disc.

Collimation refers to the distribution of angles of incidence of the flux as it strikes substrate 24. “Well-collimated” deposition refers to limiting or narrowing the angular distribution to a defined range of angles around the desired deposition angle, or angle of incidence, θ. Generally, a smaller angular distribution of the deposition flux will result in a more uniform distribution of the tilt angle in the deposited material.

The orientation of holes 30 in block 28 limits the passage of deposition flux through collimator 26 to those deposition particles moving at an incident angle within a limited range surrounding angle θ. The distribution of incident angles allowed by collimator 26 is controllable by modifying the size and shape of each hole 30, and by modifying the thickness of block 28. Modifying the shape and decreasing the size of each hole 30 and/or increasing the thickness of block 28 reduces the distribution of the angles of incidence. The smaller the range or distribution of allowed angles of incidence, the more collimated or well-collimated the flux.

The angle of the holes 30 in block 28 of collimator 26 provides oblique collimation of the deposition species, resulting in oblique deposition on the surface of substrate 24. The collimator 26 directs the oblique deposition relative to a central axis thereby resulting in a tilted thin layer on substrate 24 with the desired orientation, pattern and symmetry, including azimuthal symmetry and radial pattern. Symmetry and pattern are further detailed below. Collimator 26 can be modified to deposit other patterns, such as a circumferential pattern, by orienting the tilt of the holes 30 and arranging the holes 30 to the desired pattern and orientation. In order to provide a high degree of azimuthal symmetry and uniformity in thickness in the tilted thin layer, the substrate 24 is desirably rotated during deposition.

The distribution of holes 30 in block 28 of collimator 26 need not be uniform. The distribution of holes 30 is preferably customized to the flux density distribution of the deposition source in order to deposit films of a uniform thickness. The distribution profile of the vaporized species leaving source 22 is generally not uniform and will be dependent on the exact geometry of the source, as well as other factors known in PVD processes. The distribution profile additionally changes with distance from the source, therefore the distribution profile of flux at collimator 26 and the distribution profile of flux at substrate 24 depends on the source-to-collimator and the collimator-to-substrate distance. By controlling the distribution of holes 30 and the relative spacing from substrate 24 to collimator 26 to source 22, the distribution of vaporized species (flux) reaching the substrate 24 can be improved in uniformity.

Holes 30 have circular cross-sectional shapes as shown in FIG. 2, but other cross-sectional shapes are also possible. Other cross-sectional shapes for a hole 30 include, but are not limited to: ovals, wedges, rhombus, triangle or shapes derived therefrom. The block 28 of collimator 26 may also be modified to optimize performance, for example to improve film uniformity, by curving or otherwise modifying the surface of block 28 into an alternative topography thereby influencing the spacing from substrate 24 to collimator 26 to source 22.

The deposition system 20 and collimator 26 may be used with any type of conventional PVD process. The deposition source 22 is not limited to a particular source type. The source 22 is preferably optimized to maximize flux passing through collimator 26. The source dimensions and geometric shape are chosen so that the flux distribution matches the dimensions of collimator 26 thereby focusing the flux on holes 30. Source 22 may comprise a singe source or may comprise multiple sources arranged to act in concert. For example, using collimator 26 in sputter deposition, the source 22 is preferably a ring with a much larger outer diameter than the substrate diameter, one particular type being a ring-type sputter cathode. The source 22 may also be canted toward the collimator 26 to increase deposition flux.

The deposition system 20 including source 22 as shown in FIG. 2 is oriented such that the vaporized species travel upward (opposite of gravity) to reach substrate 24. The deposition system 20 may alternatively be oriented in any direction, including with the direction of gravity, sideways, or in a zero gravity environment. In all cases, the surface of the substrate 24 upon which the tilted thin film was deposited faces towards the collimator 26 and source 22.

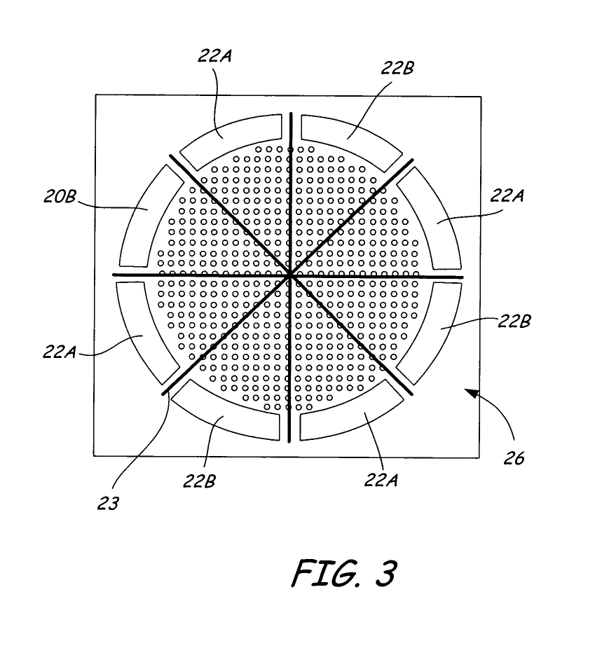

Alternatively, source 22 may comprise multiple individual sources arranged circumferentially relative to the collimator as shown in FIG. 3. Where multiple individual sources are used, the sources may include different deposition materials and/or sources of different types. An example arrangement is shown in FIG. 3 where four sputter cathodes of a first source 22A and four evaporators of a second source 22B are arranged with circumferential geometry relative to collimator 26. A set of sectioning walls 23 is used to separate the different sources and materials to minimize cross-contamination. The substrate (not shown) is rotated to facilitate uniform deposition. The arrangement shown in FIG. 3 allows the oblique co-deposition of different materials. It also allows the deposition of a first material or by a first source 22A immediately followed by the deposition of a second material or by a second source 22B, thereby minimizing the time lag and the exposure of the substrate (not shown) to poor vacuum, a known critical factor in some deposition processes.

A low pressure or vacuum environment is generally required for oblique deposition using physical vapor deposition processes in order to reduce scattering of deposition particles via collision with residual gas molecules/atoms. Scattering during the collisions can randomize the direction of the incident vapor flux, therefore control of directionality of the flux is reduced or lost (a process also referred to as “thermalization” of the deposition beam).

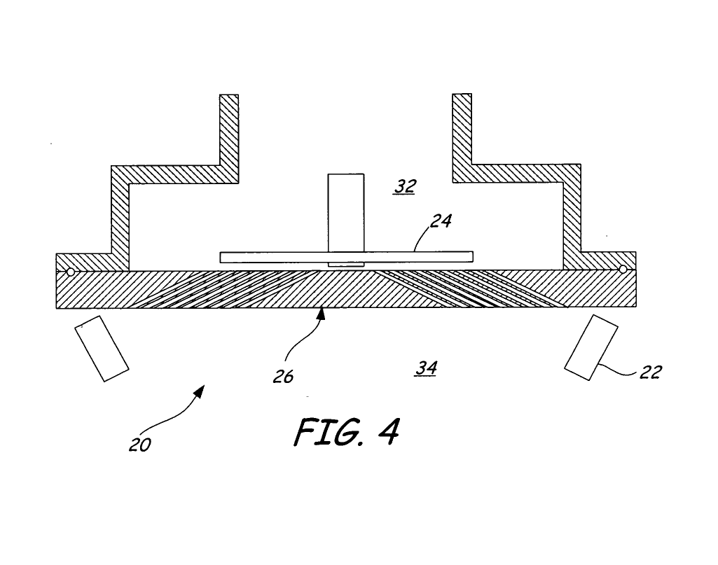

The deposition system 20, as shown in FIG. 4, can be employed to reduce thermalization of the deposition beam. The deposition system 20 additionally uses collimator 26 as a vacuum barrier to separate a first chamber 32 and a second chamber 34 as shown in FIG. 4. Use of collimator 26 as a vacuum barrier allows differential pumping of the first chamber 32 and the second chamber 34 thereby optimizing the gas pressure on each side of the collimator 26. For example, in sputter deposition, the pressure in the first chamber 32 is preferably maintained at a level of high vacuum (<0.1 mTorr) to minimize scattering of the flux after collimation as the flux nears the substrate 24. The deposition system 20 may then use a higher pressure in the second chamber 34 to optimize the source 22. For example, a conventional plasma sputter source will preferentially operate at pressures above 1 mTorr. The differential pumping allows simultaneous increase in flux from source 22 while reducing thermalization near substrate 24.

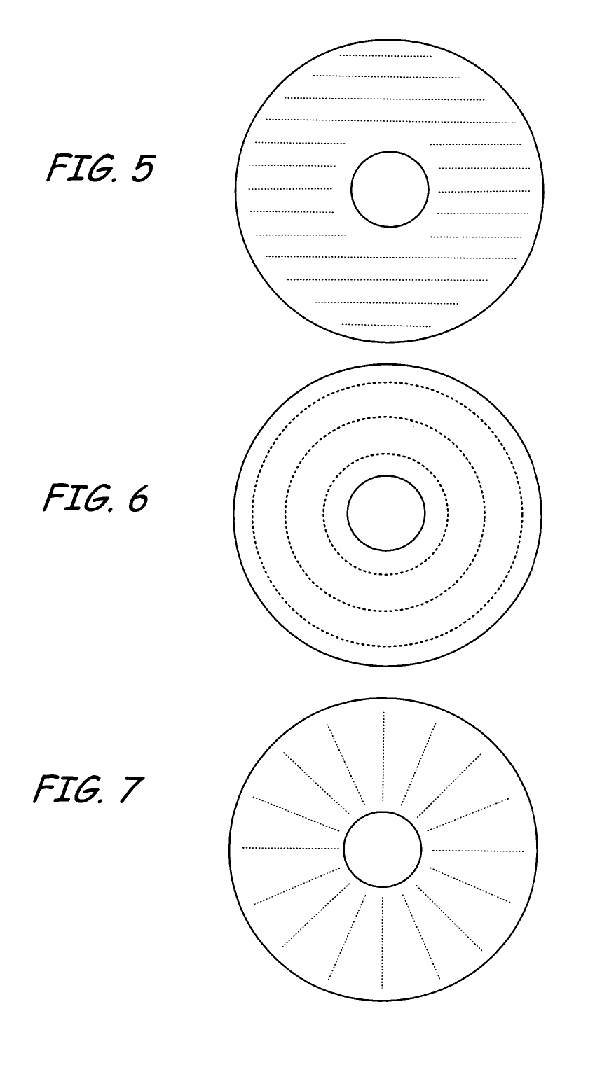

The inventive deposition system 20 may be adapted for the oblique deposition of tilted thin films with several different pattern types. While other methods primarily produced films with unidirectional pattern, the present invention additionally produces advanced pattern types, such as circumferential and radial patterns. These pattern types are further illustrated below and in FIGS. 5, 6, and 7.

A unidirectional pattern is defined as when all the grains (or other feature of interest) of the deposited film are oriented generally parallel throughout the tilted thin film. A unidirectional pattern demonstrated relative to the surface of a circular substrate is shown in FIG. 5. A unidirectional pattern is unsuitable for applications, such as hard discs, that are circular for purposes of rotation during use and consequently perform optimally where pattern is of a circular nature. The deposition system 20 of the present invention overcomes previous problems limiting the oblique deposition of tilted thin films suited for circular substrates.

Additional patterns that may be created by deposition system 20 are illustrated in FIGS. 6 and 7. The inventive deposition system is preferably utilized to deposit tilted thin films with either circumferential or radial patterns on rotating circular substrates. A circumferential pattern on a circular substrate is represented in FIG. 6. A circumferential pattern is defined as the organization of the orientations of the grains, or other feature of interest including but not limited to C-axis, crystallographic axis, easy axis, and magnetocrystalline anisotropy of the deposited material around a central point or axis.

A radial pattern on a circular substrate is represented in FIG. 7. A radial pattern is defined as the organization of the grain orientations, and/or other feature of interest including, but not limited to: C-axis, crystallographic axis, easy axis, and magnetocrystalline anisotropy, along radial axes from a central point.

It is especially desirable for certain applications using circular substrates to have azimuthal symmetry in the tilted thin films thereon. Azimuthal symmetry is defined by identity between cross-sections of the thin film taken through the center. For example, a tilted thin film deposited on a circular wafer will possess azimuthal symmetry when cross sections taken along a radius to the central axis are the same in appearance, in other words, are symmetrical. Azimuthal symmetry combined with a circumferential or a radial pattern in the magnetic anisotropy of the tilted thin film is desired for applications such as magnetic storage media (e.g. hard discs), so that the magnetic storage media “looks” consistent (does not vary other than the stored signals) as the media rotates relative to the transducing head.

The inventive deposition system is especially useful in conjunction with methods and structures involving magnetic materials. In magnetic materials, the symmetry, pattern or orientation of the titled thin film may be focused on the magnetic anisotropy. The magnetic anisotropy is of special interest in hard drive technologies where there is much interest in creating thin films with tilted magnetic anisotropy, also called tilted media. The deposition system 20 of the present invention is capable of the required control of the distribution of the angles of incidence of the vaporized species for applications demanding high quality thin films.

It is advantageous to combine the teachings of the present invention with the teachings of U.S. patent application Ser. No. ______, “Magnetic Storage Media Having Tilted Magnetic Anisotropy,” by Kalman Pelhos, Timothy J. Klemmer, and Michael A. Seigler, filed concurrently with the present application and incorporated herein by reference, hereinafter referred to as the “Tilted Media Application”. The combination of the Tilted Media Application with the teachings of the present invention is useful to produce magnetic media with tilted C-axis and tilted magnetic anisotropy, wherein the tilted C-axis and tilted magnetic anisotropy are arranged in a circumferential or a radial pattern and additionally possess azimuthal symmetry.

The deposition system 20 incorporating collimator 26 allows the adaptation of conventional high-throughput physical vapor deposition processes for oblique deposition of tilted thin film. In addition to improving deposition rates and uniformity over other oblique deposition techniques; the inventive depositions system 20, inventive collimator 26 and method of use offers improved control of the incident angle distribution resulting in the deposition of high quality tilted thin films.

Although the present invention has been described with reference to examples and preferred embodiments, workers skilled in the art will recognize that changes may be made in form and detail without departing from the spirit and scope of the invention.

1. A deposition system for oblique deposition comprising:
a source of vaporized species;
a substrate contacted by vaporized species forming a tilted thin film; and
a collimator having an array of holes oriented at approximately an oblique angle θ, the collimator placed between the source and the substrate to limit the passage to vaporized species traveling at approximately an oblique angle θ.

2. The deposition system of claim 1 wherein the oblique angle θ is greater than 35° and less than 90°.

3. The deposition system of claim 1 wherein the oblique angle θ is greater than 55° and less than 75°.

4. The deposition system of claim 1 wherein the holes are arranged in a radial pattern.

5. The deposition system of claim 1 wherein the holes are arranged so that the vaporized species passing through the collimator subsequently contact the substrate to form a radial pattern in the tilted thin film.

6. The deposition system of claim 1 wherein the holes are arranged in a circumferential pattern.

7. The deposition system of claim 1 wherein the holes are arranged so that the vaporized species passing through the collimator subsequently contact the substrate to form a circumferential pattern in the tilted thin film.

8. The deposition system of claim 1 wherein the holes are arranged so that the vaporized species passing through the collimator subsequently contact the substrate to form a tilted thin film with azimuthal symmetry.

9. A method for collimated oblique deposition onto a substrate, the method comprising:
placing a collimator between a source of a material and the substrate, wherein the collimator has a surface, and the collimator has openings tilted at an angle relative to a surface normal;
applying energy such that vaporized species leave the source and travel through the openings; and
depositing the vaporized species on the substrate resulting in a tilted thin film.

10. The method of claim 9 additionally comprising:
applying differential pumping such that a first chamber is subjected to a first pressure and a second chamber is subjected to a second pressure where the first pressure is less than the second pressure.

11. The method of claim 9 wherein the angle is greater than approximately 55° and less than approximately 75°.

12. The method of claim 9 wherein the openings are arranged in a radial pattern.

13. The method of claim 9 wherein the vaporized species are deposited on the substrate in a radial pattern.

14. The method of claim 9 wherein the openings are arranged in a circumferential pattern.

15. The method of claim 9 wherein the vaporized species are deposited on the substrate in a circumferential pattern.

16. A method of forming a magnetic storage media on a substrate, the magnetic storage media comprising at least one thin film tilted at an angle relative to a surface normal and having azimuthal symmetry, the method comprising:
depositing one or more materials through a collimator onto a substrate, wherein the collimator has openings tilted at an angle greater than 45° and less than 90° relative to a surface normal; and
rotating the substrate during deposition.

17. The method of claim 16, wherein the materials are from a source, the method additionally comprising:
applying a first vacuum between the collimator and substrate;
applying a second vacuum between the collimator and the source; and
applying differential pumping such that the substrate is subjected to a first pressure and the source is subjected to a second pressure where the first pressure is less than the second pressure.

18. The method of claim 16 wherein the openings are distributed across the collimator for deposition of the materials at a substantially uniform thickness.

19. A collimator for oblique deposition of a deposition beam resulting in a tilted thin film with azimuthal symmetry, the collimator comprising:
a block for intercepting a portion of the deposition beam, the block having a surface and a center; and
a plurality of openings in the block for passage of a portion of the deposition beam, the openings being tilted at an angle relative to an axis drawn normal to the block.

20. The collimator of claim 1 wherein the angle is greater than 35° and less than 90°.

21. The collimator of claim 19 wherein the angle is greater than 55° and less than 75°.

22. The collimator of claim 19 wherein the openings are arranged in a radial pattern.

23. The collimator of claim 19 wherein the opening are arranged in a circumferential pattern.
